(19) United States
(12) Patent Application Publication
(10) Pub. No.: US 2009/0289307 A1
(43) Pub. Date: Nov. 26, 2009

(54) SEMICONDUCTOR DEVICE

(75) Inventor: Hironobu Fukui, Kanagawa (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/470,947

(22) Filed: May 22, 2009

(30) Foreign Application Priority Data
May 26, 2008 (JP) 2008-137104

(51) Int. Cl. H01L 27/092

(52) U.S. Cl. 257/372; 257/E27.063

(57) ABSTRACT

A semiconductor device according to one embodiment includes: a semiconductor substrate having a SRAM region; an N-type element region formed in the SRAM region on the semiconductor substrate and including N-type source/drain regions; a P-type element region formed in the SRAM region on the semiconductor substrate so as to be substantially parallel to the N-type element region and including P-type source/drain regions; P-type well contact connections and N-type well contact connections formed on both sides of the N-type and P-type element regions in a longitudinal direction outside the SRAM region on the semiconductor substrate, respectively; an element isolation region for isolating the N-type element region, the P-type element region, the P-type well contact connection and the N-type well contact connection; a P-type well continuously formed under the N-type element region and the P-type well contact connection in the semiconductor substrate, and an N-type well continuously formed under the P-type element region and the N-type well contact connection in the semiconductor substrate.

### CROSS-REFERENCE TO RELATED APPLICATIONS

This application is based upon and claims the benefit of priority from prior Japanese Patent Application No. 2008-137104, filed on May 26, 2008, the entire contents of which are incorporated herein by reference.

### BACKGROUND

In accordance with miniaturization of a semiconductor device in recent years, generation of a leak current between adjacent element regions via an element isolation region has been a problem. When element regions of different conductivity types are adjacent to each other, since a source/drain region in one element region has the same conductivity type as a well in another element region, a leak current may be generated therebetween.

In order to avoid this problem, there is a method in which a depth of well is made shallow with respect to that of an element isolation region between the element regions of different conductivity types. However, since it is difficult to embed an insulating film in a region having a large aspect ratio, it is difficult to deepen the depth of the element isolation region while maintaining an element isolation width thereof. In addition, since well resistance increases when the depth of the well is made shallow, it is difficult to uniformly maintain an electric potential in the well. Furthermore, a well concentration has to be increased for reducing the depth of the well without decreasing the well resistance, however, when the well concentration is increased, parasitic capacity between the well and the source/drain region in the element region is increased.

On the other hand, a semiconductor device having a structure in which a well under an element isolation region between element regions is shallow has been known. This semiconductor device, for example, is described in JP-A-2003-188270. However, if the well under the element isolation region is made shallow, well resistance decreases in such region, and thus, it may become difficult to uniformly maintain a well electric potential.

### BRIEF SUMMARY

A semiconductor device according to one embodiment includes: a semiconductor substrate having a SRAM region; an N-type element region formed in the SRAM region on the semiconductor substrate and including N-type source/drain regions; a P-type element region formed in the SRAM region on the semiconductor substrate so as to be substantially parallel to the N-type element region and including P-type source/drain regions; P-type well contact connections and N-type well contact connections formed on both sides of the N-type and P-type element regions in a longitudinal direction outside the SRAM region on the semiconductor substrate, respectively; an element isolation region for isolating the N-type element region, the P-type element region, the P-type well contact connection and the N-type well contact connection; a P-type well continuously formed under the N-type element region and the P-type well contact connection in the semiconductor substrate; and an N-type well continuously formed under the P-type element region and the N-type well contact connection in the semiconductor substrate; wherein a depth from a surface of the semiconductor substrate in at least a portion of the P-type well on the P-type element region side under a first region is shallower than that in the P-type well under a third region, the first region is a region between the N-type element region and the closest P-type element region, and the third region is a region between the N-type element region and the P-type well contact connection; wherein a depth from the surface of the semiconductor substrate in at least a portion of the N-type well on the N-type element region side under the first region and under a second region is shallower than that in the N-type well under a fourth region, the second region is a region which extends in the longitudinal direction from the first region within a range adjacent to the N-type element region, and the fourth region is between the P-type element region and the N-type well contact connection.

A semiconductor device according to another embodiment includes: a semiconductor substrate; a first element region formed on the semiconductor substrate and including first source/drain regions having a first conductivity type; a second element region formed on the semiconductor substrate so as to be substantially parallel to the first element region and including second source/drain regions having a second conductivity type that is different from the first conductivity type; second well contact connections having the second conductivity type and first well contact connections having the first conductivity type formed on both sides of the first and second element regions in a longitudinal direction on the semiconductor substrate, respectively; an element isolation region for isolating the first element region, the second element region, the second well contact connection and the first well contact connection; a second well continuously formed under the first element region and the second well contact connection in the semiconductor substrate, and having the second conductivity type; and a first well continuously formed under the second element region and the first well contact connection in the semiconductor substrate, and having the first conductivity type; wherein a depth from a surface of the semiconductor substrate in at least a portion of the second well on the second element region side under a first region is shallower than that in the second well under a region between the first element region and the second well contact connection, and the first region is a region between the first element region and the closest second element region; wherein a depth from the surface of the semiconductor substrate in at least a portion of the first well on the first element region side under the first region and under a second region is shallower than that in the first well under a region between the second element region and the first well contact connection, and the second region is a region which extends in the longitudinal direction from the first region within a range adjacent to the first element region.

A semiconductor device according to another embodiment includes: a semiconductor substrate; a P-type element region formed on the semiconductor substrate; an N-type element region formed on the semiconductor substrate; a P-type well contact connection formed on the semiconductor substrate; an N-type well contact connection formed on the semiconductor substrate; an element isolation region for isolating the P-type element region, the N-type element region, the P-type well contact connection and the N-type well contact connection; a P-type well continuously formed under the N-type element region and the P-type well contact connection in the semiconductor substrate; and an N-type well continuously formed under the P-type element region and the N-type well contact connection in the semiconductor substrate; wherein the P-type and N-type element regions are located closer than a predetermined distance from a boundary between the P-type and N-type wells; a first depth from the surface of the semiconductor substrate in a region of the P-type well within the predetermined distance from the boundary is shallower than a depth from the surface of the semiconductor substrate in a region of the P-type well between the N-type element region and the P-type well contact connection; and a second depth from the surface of the semiconductor substrate in a region of the N-type well within the predetermined distance from the boundary is shallower than a depth from the surface of the semiconductor substrate in a region of the N-type well between the P-type element region and the N-type well contact connection.

### BRIEF DESCRIPTION OF THE DRAWING

FIG. 1 is a top view schematically showing a configuration of a semiconductor device according to a first embodiment;

FIGS. 2A and 2B are cross sectional views when cut surfaces respectively taken on lines A-A and B-B of FIG. 1 are viewed in a direction indicated by arrows in the figure;

FIGS. 3A and 3B are cross sectional views when cut surfaces respectively taken on lines C-C and D-D of FIG. 1 are viewed in a direction indicated by arrows in the figure;

FIGS. 4A and 4B are cross sectional views showing a semiconductor device according to a second embodiment;

FIGS. 5A and 5B are cross sectional views showing the semiconductor device according to the second embodiment;

FIG. 6 is a top view schematically showing a configuration of a logic circuit region of a semiconductor device according to a third embodiment; and

FIGS. 7A and 7B are cross sectional views when cut surfaces respectively taken on lines E-E and F-F of FIG. 6 are viewed in a direction indicated by arrows in the figure.

### DETAILED DESCRIPTION

### First Embodiment

### Structure of Semiconductor Device

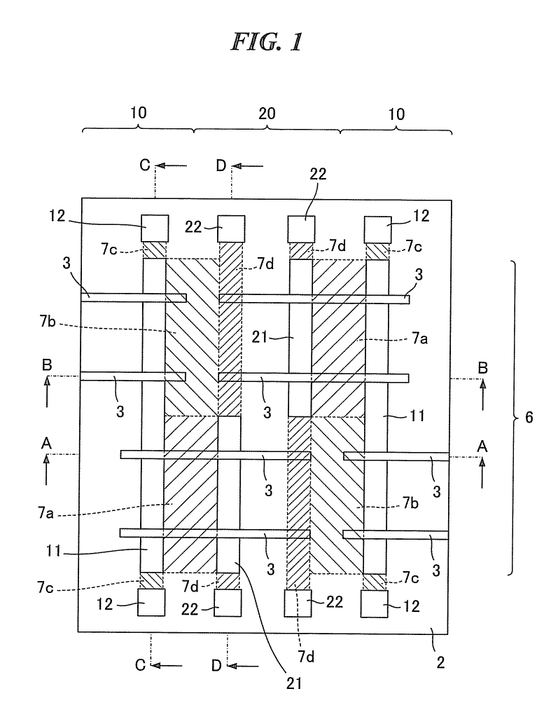

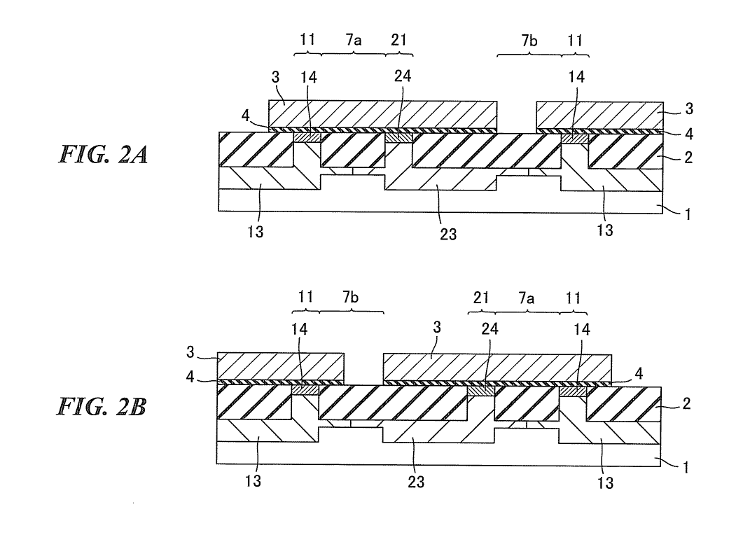

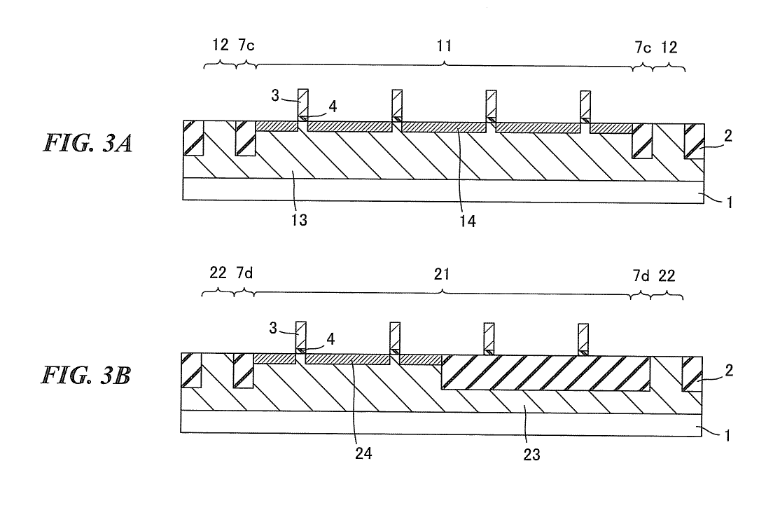

FIG. 1 is a top view schematically showing a configuration of a semiconductor device according to a first embodiment. In addition, FIGS. 2A and 2B are cross sectional views when cut surfaces respectively taken on lines A-A and B-B of FIG. 1 are viewed in a direction indicated by arrows in the figure. In addition, FIGS. 3A and 3B are cross sectional views when cut surfaces respectively taken on lines C-C and D-D of FIG. 1 are viewed in a direction indicated by arrows in the figure.

A semiconductor device according to the present embodiment has a semiconductor substrate 1 having a SRAM region 6, an N-type element region 11 and a P-type element region 21 that are formed substantially parallel to each other in the SRAM region 6 on the semiconductor substrate 1, P-type well contact connections 12 and N-type well contact connections 22 formed on both sides of the N-type element region 11 and the P-type element region 21 in a longitudinal direction of the N-type element region 11 and the P-type element region 21 outside the SRAM region 6 on the semiconductor substrate 1 respectively, an element isolation region 2 for isolating the N-type element region 11, the P-type element region 21, the P-type well contact connections 12 and the N-type well contact connections 22, a P-type well 13 continuously formed under the N-type element region 11 and the P-type well contact connection 12 in the semiconductor substrate 1, an N-type well 23 continuously formed under the P-type element region 21 and the N-type well contact connection 22 in the semiconductor substrate 1, and a gate electrode 3 formed commonly on the N-type element region 11 and the adjacent P-type element region 21 via a gate insulating film 4. Note that, in FIG. 1, a region in which the P-type well 13 is formed is shown as a P-type well forming region 10, and a region in which the N-type well 23 is formed is shown as an N-type well forming region 20.

The semiconductor substrate 1 is made of, e.g., a Si-based single crystal such as single crystal Si, etc.

The element isolation region 2 is made of an insulating material such as SiO₂, etc., and has, e.g., a STI (Shallow Trench Isolation) structure.

The gate electrode 3 is made of, e.g., Si-based polycrystalline such as polycrystalline Si, etc., containing a conductivity type impurity, a metal such as W, Ta, Ti, Hf, Zr, Ru, Pt, Ir, Mo or Al, etc., or a metal compound such as TiN, etc.

The gate insulating film 4 is made of, e.g., SiO₂, SiN, SiON, or a high-dielectric material (e.g., an Hf-based material such as HfSiON, HfSiO or HfO, etc., a Zr-based material such as ZrSiON, ZrSiO or ZrO, etc., and a Y-based material such as Y₂O₃, etc.).

The N-type element region 11 includes N-type source/drain regions 14 formed on both sides of the gate electrode 3. The N-type source/drain region 14 contains an n-type impurity such as As or P, etc.

The P-type element region 21 includes P-type source/drain regions 24 formed on the both sides of the gate electrode 3. The P-type source/drain region 24 contains a p-type impurity such as B, BF₂ or In, etc.

The P-type well contact connection 12 is a region for connecting a well contact that is connected to the P-type well 13. Meanwhile, the N-type well contact connection 22 is a region for connecting a well contact that is connected to the N-type well 23. Note that, although the P-type well contact connections 12 and the N-type well contact connections 22 are arranged on both sides of the SRAM region 6 including one SRAM cell in a longitudinal direction of the N-type element region 11 and the P-type element region 21 in FIGS. 1, 2A and 2B, the P-type well contact connections 12 and the N-type well contact connections 22 may be configured to be arranged on both sides of a SRAM region 6 including plural SRAM cells in a longitudinal direction of the N-type element region 11 and the P-type element region 21.

A first region 7a is a region between the N-type element region 11 and the closest P-type element region 21, and a second region 7b is a region extending from the first region 7a in a longitudinal direction of the N-type element region 11 within a range adjacent to the N-type element region 11. A boundary between the P-type well 13 and the N-type well 23 is located immediately under the first region 7a and the second region 7b. Therefore, in a region under the first region 7a, the N-type source/drain regions 14 of the N-type element region 11 are close to the N-type well 23 and the P-type source/drain regions 24 of the P-type element region 21 are close to the P-type well 13 respectively, and thus, a leak current is likely to be generated therebetween.

A depth from a surface of the semiconductor substrate 1 (a depth from an interface between the semiconductor substrate 1 and the gate insulating film 4) in at least a portion of the P-type well 13 on the P-type element region 21 side under the first region 7a is shallower than that in the P-type well 13 under a third region 7c between the N-type element region 11 and the P-type well contact connection 12.

In order to maintain a well electric potential of the P-type well 13 constant, the P-type well 13 under the third region 7c is formed to have an enough depth under the element isolation region 2. On the other hand, for the purpose of reducing a region adjacent to the P-type source/drain regions 24 for suppressing generation of a leak current, the P-type well 13 under the first region 7a is formed shallow since the depth thereof hardly affects the well electric potential of the P-type well 13.

In addition, under a region between the adjacent N-type element regions 11, there is no risk that the leak current is generated between the source/drain regions and the well. Therefore, the P-type well 13 under this region is preferably formed deeper than the P-type well 13 under the first region 7a in order to maintain the well electric potential of the P-type well 13 more uniform. In other words, a depth from the surface of the semiconductor substrate 1 in at least a portion of the P-type well 13 on the P-type element region 21 side under the first region 7a is preferably shallower than that in the P-type well 13 under the region between the adjacent N-type element regions 11.

Note that, the P-type well 13 under the second region 7b is distant from the P-type source/drain regions 24, thus, the leak current is less likely to be generated therebetween. Therefore, the P-type well 13 under this region may be formed deeper than the P-type well 13 under the first region 7a in order to maintain the well electric potential of the P-type well 13 more uniform. In other words, a depth from the surface of the semiconductor substrate 1 in at least a portion of the P-type well 13 on the P-type element region 21 side under the first region 7a may be shallower than that in the P-type well 13 under the second region 7b.

In addition, in order to suppress generation of a leak current more effectively, the P-type well 13 under the first region 7a is preferably formed such that a depth from the surface of the semiconductor substrate 1 in all portions thereof is shallower than that in the P-type well 13 under the third region 7c.

A depth from the surface of the semiconductor substrate 1 in at least a portion of the N-type well 23 on the N-type element region 11 side under the first region 7a and the second region 7b is shallower than that in the N-type well 23 under a fourth region 7d between the P-type element region 21 and the N-type well contact connection 22.

In order to maintain a well electric potential of the N-type well 23 constant, the N-type well 23 under the fourth region 7d is formed to have an enough depth under the element isolation region 2. On the other hand, for the purpose of reducing a region adjacent to the N-type source/drain regions 14 for suppressing generation of a leak current, the N-type well 23 under the first region 7a and the second region 7b is formed shallow since the depth thereof hardly affects the well electric potential of the N-type well 23.

Note that, under a region between the second region 7b and the P-type element region 21, there is no risk that the leak current is generated between the source/drain regions and the well. Therefore, the N-type well 23 under this region is preferably formed deeper than the N-type well 23 under the first region 7a and the second region 7b in order to maintain the well electric potential of the N-type well 23 more uniform. In other words, a depth from the surface of the semiconductor substrate 1 in at least a portion of the N-type well 23 on the N-type element region 11 side under the first region 7a and the second region 7b is preferably shallower than that in the N-type well 23 under the region between the second region 7b and the P-type element region 21.

In addition, in order to suppress generation of a leak current more effectively, the N-type well 23 under the first region 7a and the second region 7b is preferably formed such that a depth from the surface of the semiconductor substrate 1 in all portions thereof is shallower than that in the N-type well 23 under the fourth region 7d.

### Effect of the First Embodiment

According to the first embodiment, it is possible to suppress generation of a leak current between the P-type well 13 and the P-type source/drain regions 24 and between the N-type well 23 and the N-type source/drain regions 14 in the SRAM region 6 while maintaining a well electric potential of the P-type well 13 and the N-type well 23 sufficiently high.

### Second Embodiment

The second embodiment is different from the first embodiment in a depth of a P-type well under an N-type element region and a depth of an N-type well under a P-type element region. Note that, the explanation will be omitted or simplified for the points same as the first embodiments.

### Structure of Semiconductor Device

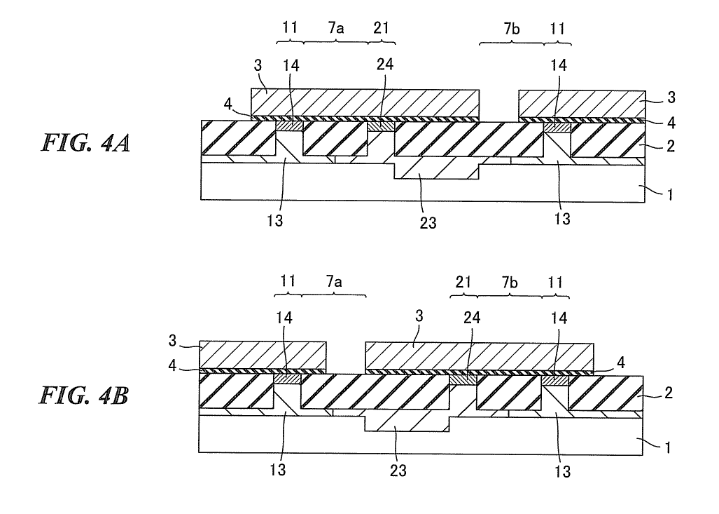

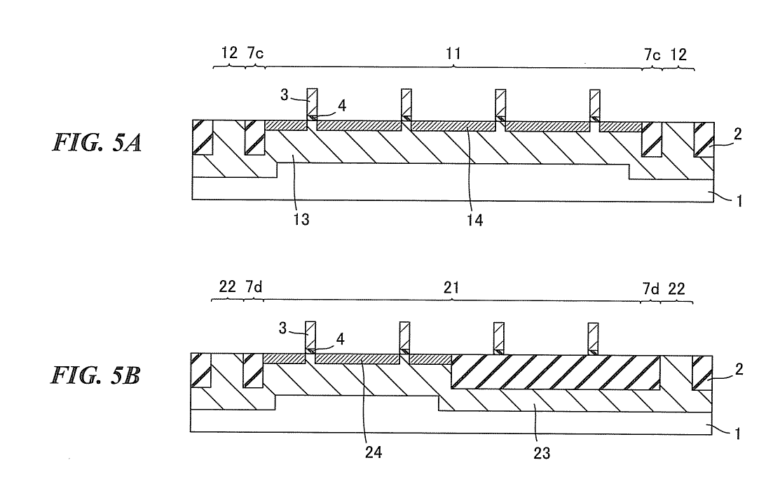

FIGS. 4A, 4B, 5A and 5B are cross sectional views showing a semiconductor device according to a second embodiment. Here, the cross sections shown in FIGS. 4A and 4B correspond to the cross sections shown in FIGS. 2A and 2B, respectively, and the cross sections shown in FIGS. 5A and 5B correspond to the cross sections shown in FIGS. 3A and 3B, respectively.

In the present embodiment, similarly to the P-type well 13 under the first region 7a, the P-type well 13 under the N-type element region 11 is formed so that a depth from the surface of the semiconductor substrate 1 in at least a portion thereof is shallower than that in the P-type well 13 under the third region 7c. In addition, similarly to the N-type well 23 under the first region 7a and the second region 7b, the N-type well 23 under the P-type element region 21 is formed so that a depth from the surface of the semiconductor substrate 1 in at least a portion thereof is shallower than that in the N-type well 23 under the fourth region 7d.

### Effect of the Second Embodiment

According to the second embodiment, by shallowly forming the P-type well 13 under the N-type element region 11 and the N-type well 23 under the P-type element region 21, it is possible to suppress generation of a leak current between the P-type well 13 and the P-type source/drain regions 24 and between the N-type well 23 and the N-type source/drain regions 14 more effectively.

Alternatively, it may be configured that either the P-type well 13 under the N-type element region 11 or the N-type well 23 under the P-type element region 21 is formed shallow.

### Third Embodiment

### Structure of Semiconductor Device

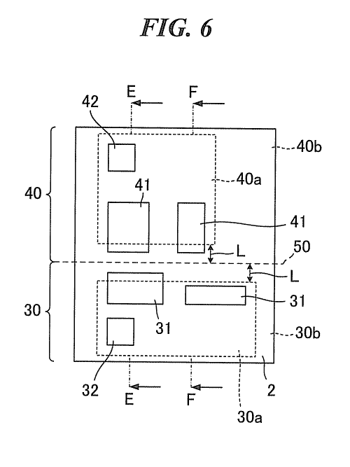

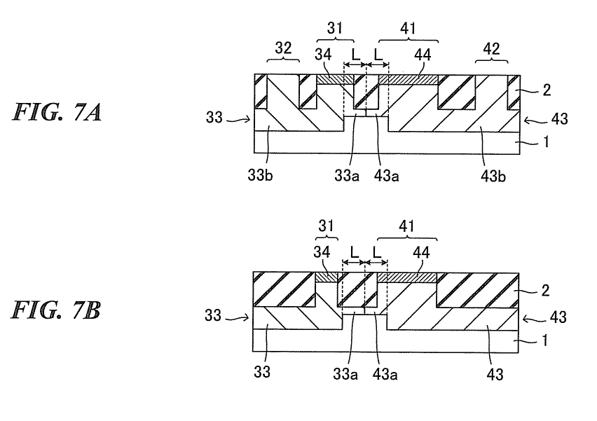

FIG. 6 is a top view schematically showing a configuration of a logic circuit region of a semiconductor device according to a third embodiment. In addition, FIGS. 7A and 7B are cross sectional views when cut surfaces respectively taken on lines E-E and F-F of FIG. 6 are viewed in a direction indicated by arrows in the figure.

A semiconductor device according to the present embodiment has a semiconductor substrate 1, an N-type element region 31 and a P-type element region 41 that are formed on the semiconductor substrate 1, a P-type well contact connection 32 and an N-type well contact connection 42 that are formed on the semiconductor substrate 1, an element isolation region 2 for isolating the N-type element region 31, the P-type element region 41, the P-type well contact connection 32 and the N-type well contact connection 42, a P-type well 33 continuously formed under the N-type element region 31 and the P-type well contact connection 32 in the semiconductor substrate 1, and an N-type well 43 continuously formed under the P-type element region 41 and the N-type well contact connection 42 in the semiconductor substrate 1. Note that, the explanation will be omitted or simplified for the points same as the first embodiments.

Although a gate electrode is formed on the N-type element region 31 and the P-type element region 41 via a gate insulating film, the illustration is omitted. In addition, the N-type element region 31 and the P-type element region 41 include an N-type source/drain region 34 and a P-type source/drain region 44 respectively.

At least one of the P-type element regions 41 and at least one of the N-type element regions 31 are located closer than a predetermined distance L (the distance L is in a direction horizontal to the surface of the semiconductor substrate 1) from a boundary 50 between a P-type well forming region 30 and an N-type well forming region 40 (between the P-type well 33 and the N-type well 43).

The P-type well 33 and the N-type well 43 have regions 33a and 43a in which the depth from the surface of the semiconductor substrate 1 is shallow, and regions 33b and 43b in which the depth from the surface of the semiconductor substrate 1 is deep, respectively. Note that, in FIG. 6, regions in which the P-type well 33, the shallow region 33a and the deep region 33b are formed are shown as the P-type well forming region 30, a region 30a and a region 30b, respectively. In addition, regions in which the N-type well 43, the shallow region 43a and the deep region 43b are formed are shown as the N-type well forming region 40, regions 40a and a region 40b, respectively.

A region of the P-type well 33 within the predetermined distance L from the boundary 50 is included in the shallow region 33a. Meanwhile, a region of the P-type well 33 between the N-type element region 31 and the P-type well contact connection 32 is included in the deep region 33b. In other words, a depth from the surface of the semiconductor substrate 1 in the region of the P-type well 33 within the predetermined distance L from the boundary 50 is shallower than that in the region of the P-type well 33 between the N-type element region 31 and the P-type well contact connection 32. By shallowly forming the region of the P-type well 33 within the predetermined distance L from the boundary 50, it is possible to suppress generation of a leak current between the P-type well 33 and the P-type source/drain region 44. In addition, since the region of the P-type well 33 between the N-type element region 31 and the P-type well contact connection 32 has an enough depth under the element isolation region 2, it is possible to maintain a well electric potential of the P-type well 33 constant.

A region of the N-type well 43 within the predetermined distance L from the boundary 50 is included in the shallow region 43a. Meanwhile, a region of the N-type well 43 between the P-type element region 41 and the N-type well contact connection 42 is included in the deep region 43b. In other words, a depth from the surface of the semiconductor substrate 1 in the region of the N-type well 43 within the predetermined distance L from the boundary 50 is shallower than that in the region of the N-type well 43 between the P-type element region 41 and the N-type well contact connection 42. By shallowly forming the region of the N-type well 43 within the predetermined distance L from the boundary 50, it is possible to suppress generation of a leak current between the N-type well 43 and the N-type source/drain region 34. In addition, since the region of the N-type well 43 between the P-type element region 41 and the N-type well contact connection 42 has an enough depth under the element isolation region 2, it is possible to maintain a well electric potential of the N-type well 43 constant.

Concretely, the predetermined distance L is a distance substantially equal to a minimum width of the element isolation region (a minimum width required for suppressing generation of a leak current between source/drain regions in adjacent elements via the element isolation region). For example, the predetermined distance L in 32 nm generation is about 45 nm on the grounds that the minimum width of the element isolation region in 32 nm generation is 45 nm. If this minimum width of the element isolation region is a width required for suppressing generation of a leak current between source/drain regions, it is expected that, for example, a twice width (90 nm when the minimum width of the element isolation region is 45 nm) is required as a width of the element isolation region in order to suppress generation of a leak current between a source/drain region and a well. If a distance between the P-type element region 41 (the P-type source/drain regions 44) and the P-type well 33 in a direction horizontal to the surface of the semiconductor substrate 1 and a distance between the N-type element region 31 (the N-type source/drain regions 34) and the N-type well 43 in a direction horizontal to the surface of the semiconductor substrate 1 in the present embodiment correspond to a half width of the element isolation region 2 in the corresponding region and when these distances are less than a distance substantially equal to the minimum width of the element isolation region (less than 45 nm when the minimum width of the element isolation region is 45 nm), there is a possibility that a leak current is likely to be generated between the P-type well 33 and the P-type source/drain regions 44 of the P-type element region 41 or between the N-type well 43 and the N-type source/drain regions 34 of the N-type element region 31.

Note that, if the P-type well 33 under the N-type element region 31 is too shallow, a channel leak current is likely to be generated in the N-type element region 31, hence, a depth from the surface of the semiconductor substrate 1 in the shallow region 33a of the P-type well 33 is preferably equal to or greater than that in the element isolation region 2. Particularly, it is more preferable that the depth from the surface of the semiconductor substrate 1 in the shallow region 33a is substantially equal to that in the element isolation region 2.

Note that, if the N-type well 43 under the P-type element region 41 is too shallow, a channel leak current is likely to be generated in the P-type element region 41, hence, a depth from the surface of the semiconductor substrate 1 in the shallow region 43a of the N-type well 43 is preferably equal to or greater than that in the element isolation region 2. Particularly, it is more preferable that the depth from the surface of the semiconductor substrate 1 in the shallow region 43a is substantially equal to that in the element isolation region 2.

### Effect of the Third Embodiment

According to the third embodiment, it is possible to suppress generation of a leak current between the P-type well 33 and the P-type source/drain region 44 and between the N-type well 43 and the N-type source/drain region 34 in a logic circuit region while maintaining a well electric potential of the P-type well 33 and the N-type well 43 sufficiently high.

### Other Embodiments

It should be noted that embodiments are not intended to be limited to the above-mentioned first to third embodiments, and the various kinds of changes thereof can be implemented by those skilled in the art without departing from the gist of the invention.

In addition, the constituent elements of the above-mentioned embodiments can be arbitrarily combined with each other without departing from the gist of the invention.

What is claimed is:

1. A semiconductor device, comprising:
a semiconductor substrate having a SRAM region;
an N-type element region formed in the SRAM region on the semiconductor substrate and including N-type source/drain regions;
a P-type element region formed in the SRAM region on the semiconductor substrate so as to be substantially parallel to the N-type element region and including P-type source/drain regions;
P-type well contact connections and N-type well contact connections formed on both sides of the N-type and P-type element regions in a longitudinal direction outside the SRAM region on the semiconductor substrate, respectively;
an element isolation region for isolating the N-type element region, the P-type element region, the P-type well contact connection and the N-type well contact connection;
a P-type well continuously formed under the N-type element region and the P-type well contact connection in the semiconductor substrate; and
an N-type well continuously formed under the P-type element region and the N-type well contact connection in the semiconductor substrate;
wherein a depth from a surface of the semiconductor substrate in at least a portion of the P-type well on the P-type element region side under a first region is shallower than that in the P-type well under a third region, the first region is a region between the N-type element region and the closest P-type element region, and the third region is a region between the N-type element region and the P-type well contact connection;
wherein a depth from the surface of the semiconductor substrate in at least a portion of the N-type well on the N-type element region side under the first region and under a second region is shallower than that in the N-type well under a fourth region, the second region is a region which extends in the longitudinal direction from the first region within a range adjacent to the N-type element region, and the fourth region is between the P-type element region and the N-type well contact connection.

2. The semiconductor device according to claim 1, wherein a depth from the surface of the semiconductor substrate in at least a portion of the P-type well under the N-type element region is shallower than that in the P-type well under the third region.

3. The semiconductor device according to claim 1, wherein a depth from the surface of the semiconductor substrate in at least a portion of the P-type well on the P-type element region side under the first region is shallower than that in the P-type well under a region between the adjacent N-type element regions.

4. The semiconductor device according to claim 2, wherein a depth from the surface of the semiconductor substrate in at least a portion of the P-type well on the P-type element region side under the first region is shallower than that in the P-type well under a region between the adjacent N-type element regions.

5. The semiconductor device according to claim 1, wherein a depth from the surface of the semiconductor substrate in at least a portion of N-type well on the N-type element region side under the first and second regions is shallower than that in the N-type well under a region between the second region and the P-type element region.

6. The semiconductor device according to claim 2, wherein a depth from the surface of the semiconductor substrate in at least a portion of N-type well on the N-type element region side under the first and second regions is shallower than that in the N-type well under a region between the second region and the P-type element region.

7. The semiconductor device according to claim 1, wherein a depth from the surface of the semiconductor substrate in at least a portion of the N-type well under the P-type element region is shallower than that in the N-type well under the fourth region.

8. The semiconductor device according to claim 2, wherein a depth from the surface of the semiconductor substrate in at least a portion of the N-type well under the P-type element region is shallower than that in the N-type well under the fourth region.

9. The semiconductor device according to claim 1, wherein a depth from the surface of the semiconductor substrate in at least a portion of the P-type well on the P-type element region side under the first region is shallower than that in the P-type well under the second region.

10. The semiconductor device according to claim 1, wherein a depth from the surface of the semiconductor substrate in all portions of the P-type well under the first region is shallower than that in the P-type well under the third region.

11. The semiconductor device according to claim 1, wherein a depth from the surface of the semiconductor substrate in all portions of the N-type well under the first and second regions is shallower than that in the N-type well under the fourth region.

12. A semiconductor device, comprising:
a semiconductor substrate;
a first element region formed on the semiconductor substrate and including first source/drain regions having a first conductivity type;
a second element region formed on the semiconductor substrate so as to be substantially parallel to the first element region and including second source/drain regions having a second conductivity type that is different from the first conductivity type;
second well contact connections having the second conductivity type and first well contact connections having the first conductivity type formed on both sides of the first and second element regions in a longitudinal direction on the semiconductor substrate, respectively;
an element isolation region for isolating the first element region, the second element region, the second well contact connection and the first well contact connection;
a second well continuously formed under the first element region and the second well contact connection in the semiconductor substrate, and having the second conductivity type; and
a first well continuously formed under the second element region and the first well contact connection in the semiconductor substrate, and having the first conductivity type;
wherein a depth from a surface of the semiconductor substrate in at least a portion of the second well on the second element region side under a first region is shallower than that in the second well under a region between the first element region and the second well contact connection, and the first region is a region between the first element region and the closest second element region;
wherein a depth from the surface of the semiconductor substrate in at least a portion of the first well on the first element region side under the first region and under a second region is shallower than that in the first well under a region between the second element region and the first well contact connection, and the second region is a region which extends in the longitudinal direction from the first region within a range adjacent to the first element region.

13. The semiconductor device according to claim 12, wherein the semiconductor substrate has a SRAM region;
the first and second element regions are formed in the SRAM region; and
the first and second well contact connections are formed outside the SRAM region.

14. The semiconductor device according to claim 12, wherein the first conductivity type is N-type; and
the second conductivity type is P-type.

15. A semiconductor device, comprising:
a semiconductor substrate;
a P-type element region formed on the semiconductor substrate;
an N-type element region formed on the semiconductor substrate;
a P-type well contact connection formed on the semiconductor substrate;
an N-type well contact connection formed on the semiconductor substrate;
an element isolation region for isolating the P-type element region, the N-type element region, the P-type well contact connection and the N-type well contact connection;
a P-type well continuously formed under the N-type element region and the P-type well contact connection in the semiconductor substrate; and
an N-type well continuously formed under the P-type element region and the N-type well contact connection in the semiconductor substrate;
wherein the P-type and N-type element regions are located closer than a predetermined distance from a boundary between the P-type and N-type wells;
a first depth from the surface of the semiconductor substrate in a region of the P-type well within the predetermined distance from the boundary is shallower than a depth from the surface of the semiconductor substrate in a region of the P-type well between the N-type element region and the P-type well contact connection; and
a second depth from the surface of the semiconductor substrate in a region of the N-type well within the predetermined distance from the boundary is shallower than a depth from the surface of the semiconductor substrate in a region of the N-type well between the P-type element region and the N-type well contact connection.

16. The semiconductor device according to claim 15, wherein the predetermined distance is substantially equal to a minimum width of the element isolation region required for suppressing generation of a leak current between source/drain regions in adjacent elements via the element isolation region.

17. The semiconductor device according to claim 15, wherein the first depth is equal to or greater than a depth from the surface of the semiconductor substrate in the element isolation region.

18. The semiconductor device according to claim 17, wherein the first depth is substantially equal to a depth from the surface of the semiconductor substrate in the element isolation region.

19. The semiconductor device according to claim 15, wherein the second depth is equal to or greater than a depth from the surface of the semiconductor substrate in the element isolation region.

20. The semiconductor device according to claim 19, wherein the second depth is substantially equal to a depth from the surface of the semiconductor substrate in the element isolation region.
